(19) United States
(12) Patent Application Publication
(10) Pub. No.: US 2008/0296598 A1
(43) Pub. Date: Dec. 4, 2008

(54) CURRENT SPREADING LAYER WITH MICRO/NANO STRUCTURE, LIGHT-EMITTING DIODE APPARATUS AND ITS MANUFACTURING METHOD

(76) Inventors: Horng-Jou WANG, Taoyuan Hsien (TW); Ching-Chuan Shiue, Taoyuan Hsien (TW); Shih-Peng Chen, Taoyuan Hsien (TW); Chao-Min Chen, Taoyuan Hsien (TW); Huang-Kun Chen, Taoyuan Hsien (TW)

Correspondence Address: BIRCH STEWART KOLASCH & BIRCH, PO BOX 747, FALLS CHURCH, VA, 22040-0747, US

(21) Appl. No.: 12/029,985

(22) Filed: Feb. 12, 2008

(30) Foreign Application Priority Data
May 28, 2007 (TW) 096118930

(51) Int. Cl. H01L 33/00

(52) U.S. Cl. 257/98; 438/29; 257/E33.011

(57) ABSTRACT

A light-emitting diode (LED) apparatus includes an epitaxial layer and a current spreading layer. The epitaxial layer has a first semiconductor layer, an active layer and a second semiconductor layer. The current spreading layer is disposed on the first semiconductor layer of the epitaxial layer and has a micro/nano roughing structure layer and a transparent conductive layer. The micro/nano roughing structure layer has a plurality of hollow parts, and the transparent conductive layer covers a surface of the micro/nano roughing structure layer and is filled within the hollow parts. In addition, a manufacturing method of the LED apparatus and a current spreading layer with a micro/nano structure are also disclosed.

### CROSS REFERENCE TO RELATED APPLICATIONS

This Non-provisional application claims priority under 35 U.S.C. §119(a) on Patent Application No(s). 096118930 filed in Taiwan, Republic of China on May 28, 2007, the entire contents of which are hereby incorporated by reference.

### BACKGROUND OF THE INVENTION

1. Field of Invention

The invention relates to a light-emitting diode (LED) apparatus and manufacturing method thereof. More particularly, the invention relates to a current spreading layer and a LED apparatus having a micro/nano structure, and manufacturing method thereof.

2. Related Art

A light-emitting diode (LED) apparatus is a lighting apparatus made of semiconductor materials. The LED apparatus pertaining to a cold lighting apparatus has the advantages of low power consumption, long lifetime, high response speed and small size, and can be manufactured into an extremely small or array-type apparatus. With the continuous development of the recent technology, the application range thereof covers an indicator of a computer or a house appliance product, a backlight source of a liquid crystal display (LCD) apparatus, etc.

However, the LED apparatus still has the problems in that the currents cannot be uniformly spread and that the total reflection decreases the light outputting efficiency so that the light emitting efficiency of the LED apparatus cannot be effectively enhanced.

In general, the LED apparatus may be a flip-chip type LED apparatus, a vertical type LED apparatus or a front-side type LED apparatus. In order to solve the problem of the lowed light emitting efficiency caused by the reflection, the following technology has been proposed. As shown in FIG. 1, a LED apparatus 1, such as a vertical type LED apparatus, has an n-type semiconductor doping layer 121, an active layer 122 and a p-type semiconductor doping layer 123 in sequence formed on a surface of a substrate 11. Next, a transparent conductive layer 13 is formed on the p-type semiconductor doping layer 123, and a first electrode 14 and a second electrode 15 are respectively formed on the transparent conductive layer 13 and the other surface of the substrate 11.

As shown in FIG. 1, a light outputting surface 131 of a transparent conductive layer 13 can be formed with a roughing surface in order to prevent a light outputting surface from totally reflecting light and thus to enhance the light extracting efficiency.

As shown in FIG. 2A, another method for enhancing the light outputting efficiency is to dispose a roughing structure 16 on the light outputting surface 131 of the transparent conductive layer 13 in order to prevent the light outputting surface from totally reflecting the light and thus to enhance the light extracting efficiency.

In addition, it is also possible to directly form the roughing surface on a surface of the n-type semiconductor doping layer 121 or the p-type semiconductor doping layer 123 (see FIG. 2B) in order to prevent the light outputting surface form totally reflecting the light and thus to enhance the light extracting efficiency.

As mentioned hereinabove, although the conventional method can solve the problem of the total reflection, the structure still has the problem that the currents cannot be uniformly spread because the currents flow through the shortest circuit paths. Therefore, when the light emitting area of the LED apparatus is enlarged, the currents still cannot be uniformly distributed.

Therefore, it is an important subject to provide a current spreading layer with a micro/nano structure, a light-emitting diode (LED) apparatus and its manufacturing method that are capable of decreasing the total reflection of light and making currents be uniformly distributed.

### SUMMARY OF THE INVENTION

In view of the foregoing, the invention is to provide a current spreading layer with a micro/nano structure, a light-emitting diode (LED) apparatus and its manufacturing method that are capable of decreasing the total reflection of light and making currents be uniformly distributed.

To achieve the above, the invention discloses a current spreading layer including a micro/nano roughing structure layer and a transparent conductive layer. The current spreading layer is connected to a semiconductor structure. The micro/nano roughing structure layer has a plurality of hollow parts. The transparent conductive layer covers one surface of the micro/nano roughing structure layer and is filled within the hollow parts.

To achieve the above, the invention also discloses a light-emitting diode (LED) apparatus including an epitaxial layer and a current spreading layer. The epitaxial layer includes a first semiconductor layer, an active layer and a second semiconductor layer in sequence. The current spreading layer is connected to the epitaxial layer and has a micro/nano roughing structure layer and a transparent conductive layer. The micro/nano roughing structure layer has a plurality of hollow parts. The transparent conductive layer covers one surface of the micro/nano roughing structure layer and is filled within the hollow parts.

To achieve the above, the invention further discloses a manufacturing method of a LED apparatus. The method includes the following steps of: forming a first semiconductor layer on an epitaxial substrate; forming an active layer on the first semiconductor layer; forming a second semiconductor layer on the active layer; removing a portion of the active layer and a portion of the second semiconductor layer to expose a portion of the first semiconductor layer; forming a micro/nano roughing structure layer with a plurality of hollow parts on the second semiconductor layer; and forming a transparent conductive layer on the micro/nano roughing structure layer and within the hollow parts.

In addition, the invention also discloses a manufacturing method of a LED apparatus including the following steps of: forming a first semiconductor layer on an epitaxial substrate; forming an active layer on the first semiconductor layer; forming a second semiconductor layer on the active layer; forming a micro/nano roughing structure layer with a plurality of hollow parts on the second semiconductor layer; and forming a transparent conductive layer on the micro/nano roughing structure layer and within the hollow parts.

In summary, the current spreading layer with the micro/nano structure, the LED apparatus and its manufacturing method have the following features. First, the current spreading layer with the micro/nano structure is used in conjunction with a reflective layer, a thermoconductive insulating layer or a thermoconductive adhesive layer so that the current spreading layer with good Ohmic junction is formed in the flip-chip type, vertical type or front-side LED apparatus. Thus, the currents can be uniformly spread, the total reflection can be decreased, and the light extracting efficiency can be enhanced.

### BRIEF DESCRIPTION OF THE DRAWINGS

The invention will become more fully understood from the detailed description and accompanying drawings, which are given for illustration only, and thus are not limitative of the present invention, and wherein:

FIG. 1 is a schematic illustration showing a conventional LED apparatus;

FIGS. 2A and 2B are schematic illustrations showing other two conventional LED apparatuses;

FIG. 3 is a flow chart showing a manufacturing method of a LED apparatus according to a first embodiment of the invention;

FIGS. 4A to 4E are schematic illustrations showing structures corresponding to the steps of FIG. 3;

FIG. 5 is a flow chart showing a manufacturing method of a LED apparatus according to a second embodiment of the invention;

FIGS. 6A to 6E are schematic illustrations showing structures corresponding to the steps of FIG. 5;

FIG. 7 is a flow chart showing a manufacturing method of a LED apparatus according to a third embodiment of the invention;

FIGS. 8A to 8E are schematic illustrations showing structures corresponding to the steps of FIG. 7;

FIG. 9 is a flow chart showing a manufacturing method of a LED apparatus according to a fourth embodiment of the invention;

FIGS. 10A to 10F are schematic illustrations showing structures corresponding to the steps of FIG. 9; and

FIG. 11 is a schematic illustration showing another current spreading layer.

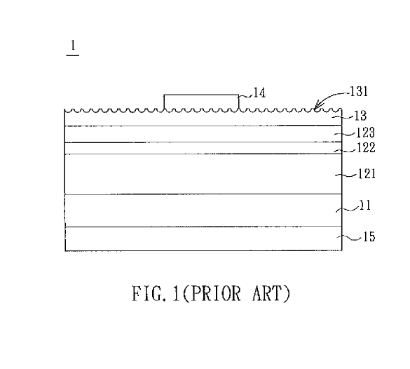

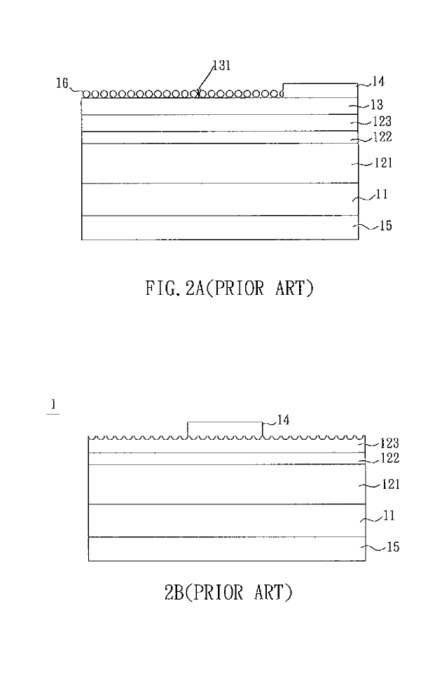

### DETAILED DESCRIPTION OF THE INVENTION

The present invention will be apparent from the following detailed description, which proceeds with reference to the accompanying drawings, wherein the same references relate to the same elements.

### First Embodiment

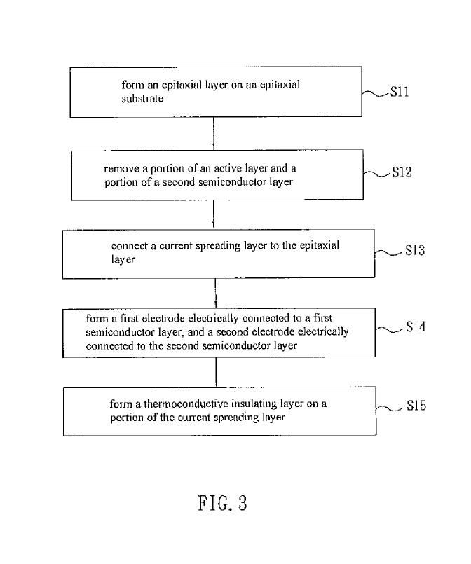

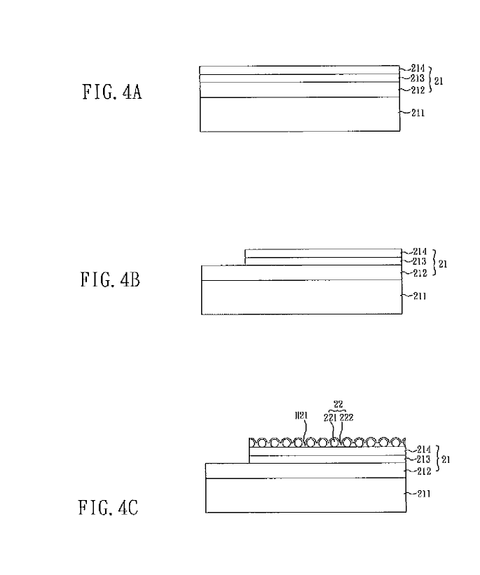

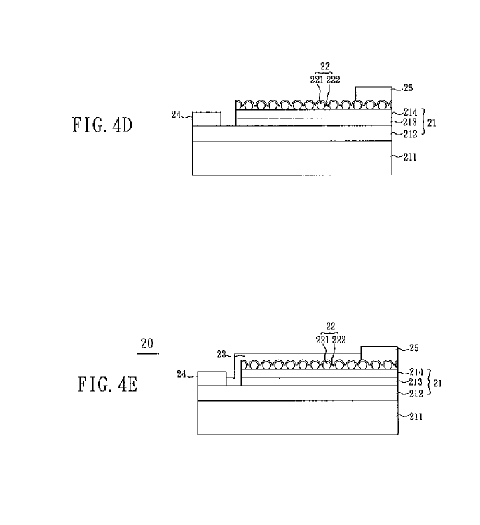

Referring to FIG. 3, a manufacturing method of a light-emitting diode (LED) apparatus 20 according to the first embodiment of the invention includes steps S11 to S15. Illustrations will be made with reference to FIGS. 4A to 4E.

As shown in FIG. 4A, in the step S11, an epitaxial layer 21 is formed on an epitaxial substrate 211. The epitaxial layer 21 includes a first semiconductor layer 212, an active layer 213 and a second semiconductor layer 214. The first semiconductor layer 212 is formed on the epitaxial substrate 211, and then the active layer 213 is formed on the first semiconductor layer 212, and then the second semiconductor layer 214 is formed on the active layer 213. Next, as shown in FIG. 4B, a portion of the active layer 213 and a portion of the second semiconductor layer 214 are removed in the step S12.

As shown in FIG. 4C, a current spreading layer 22 is connected to the epitaxial layer 21 in the step S13. In this embodiment, the current spreading layer 22 is formed with a micro/nano roughing structure layer 221 on the second semiconductor layer 214 by, without limitation to, stacking, sintering, anode aluminum oxidizing (AAO), nano-imprinting, hot pressing, etching or electron beam exposing with an E-beam writer. The micro/nano roughing structure layer 221 has a plurality of hollow parts H21. A transparent conductive layer 222 is formed on the micro/nano roughing structure layer 221 and within the hollow parts H21.

In this embodiment, the first semiconductor layer 212 and the second semiconductor layer 214 can be respectively a P-type epitaxial layer and an N-type epitaxial layer or an N-type epitaxial layer and a P-type epitaxial layer without any limitation. A refractive index of the micro/nano roughing structure layer 221 is greater than that of air and smaller than that of the epitaxial layer. According to the appearance thereof, the micro/nano roughing structure layer 221 can include a nano-ball, a nano-column, a nano-void, a nano-grid, a nano-line or a nano-concave-convex structure. Herein, the micro/nano roughing structure layer 221 includes a nano-ball, for example, and the material thereof can be aluminum oxide (Al₂O₃), silicon nitride (Si₃N₄), tin oxide (SnO₂), silicon dioxide (SiO₂), resin, polycarbonate or combinations thereof. The material of the transparent conductive layer 222 can include indium tin oxide (ITO), aluminum-doped zinc oxide (AZO) or indium zinc oxide (IZO).

As shown in FIG. 4D, a first electrode 24 electrically connected to the first semiconductor layer 212 and a second electrode 25 electrically connected to the second semiconductor layer 214 are respectively formed in the step S14.

As shown in FIG. 4E, a thermoconductive insulating layer 23 is formed on a portion of the current spreading layer 22 in the step S15 in order to provide the LED apparatus the better ability against the electrostatic charges. More specifically, the thermoconductive insulating layer can also cover the portion of the second semiconductor layer 214, the active layer 213 and the first semiconductor layer 212 to form the front-side LED apparatus 20 having the micro/nano structure.

In this embodiment, the order of the steps is not limited thereto and may be adjusted according to the actual requirement.

### Second Embodiment

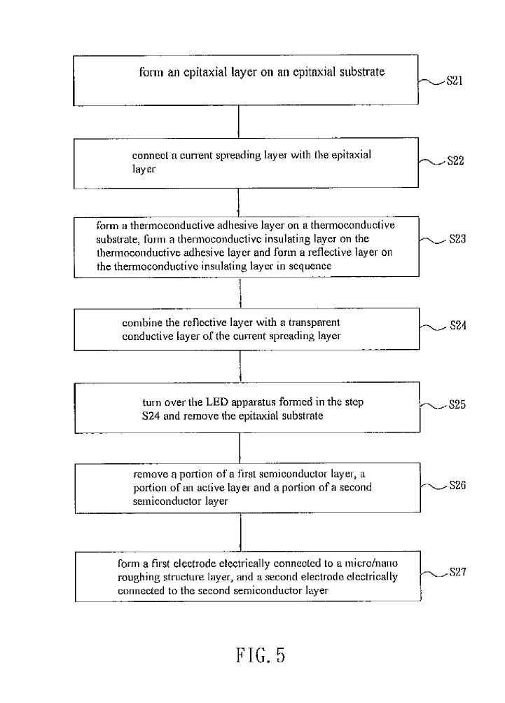

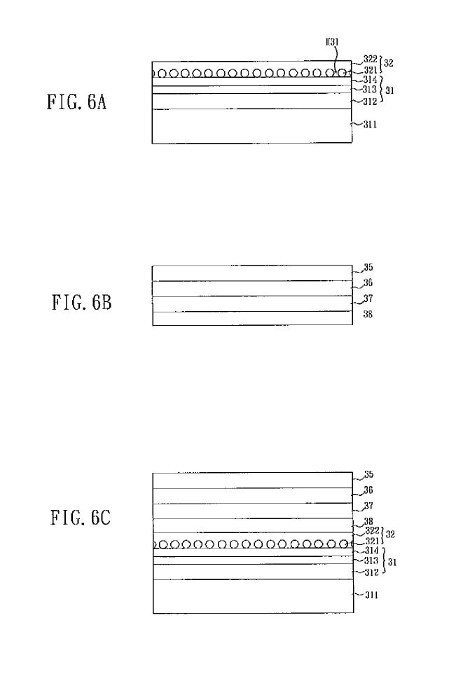

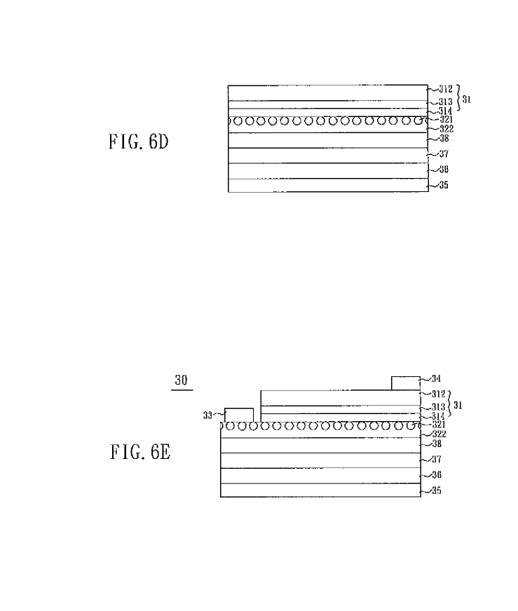

Referring to FIG. 5, a manufacturing method of a light-emitting diode (LED) apparatus 30 according to the second embodiment of the invention includes steps S21 to S27. Illustrations will be made with reference to FIGS. 6A to 6F.

As shown in FIG. 6A, an epitaxial layer 31 is formed on an epitaxial substrate 311 in the step S21 the same as the step S11 of the first embodiment. The epitaxial layer 31 includes a first semiconductor layer 312, an active layer 313 and a second semiconductor layer 314. The first semiconductor layer 312 is formed on the epitaxial substrate 31. Next, the active layer 313 is formed on the first semiconductor layer 312, and then the second semiconductor layer 314 is formed on the active layer 313.

In the step S22, a current spreading layer 32 is connected to the epitaxial layer 31. In this embodiment, the current spreading layer 32 is formed with a micro/nano roughing structure layer 321 on the second semiconductor layer 314 by, for example but not limited to, stacking, sintering, anode aluminum oxidizing (AAO), nano-imprinting, hot pressing, etching or electron beam exposing with an E-beam writer. The micro/nano roughing structure layer 321 has a plurality of hollow parts H31. A transparent conductive layer 322 is formed on the micro/nano roughing structure layer 321 and within the hollow parts H31.

As shown in FIG. 6B, in the step S23, a thermoconductive adhesive layer 36 is formed on a thermoconductive substrate 35, a thermoconductive insulating layer 37 is formed on the thermoconductive adhesive layer 36, and a reflective layer 38 is formed on the thermoconductive insulating layer 37 in sequence.

In this embodiment, the material of the thermoconductive substrate 35 can be silicon, gallium arsenide, gallium phosphide, silicon carbide, boron nitride, aluminum, aluminum nitride, copper or combinations thereof. The thermoconductive adhesive layer 36 is utilized for combining the thermoconductive insulating layer 37 with the thermoconductive substrate 35, and the material thereof can be gold, soldering paste, tin-silver paste, silver paste or combinations thereof.

The thermoconductive insulating layer 37 can prevent the epitaxial layer 31 from being electrically connected to an external device through the thermoconductive substrate 35. The material of the thermoconductive insulating layer 37 is an insulation material, such as aluminum nitride or silicon carbide, having a coefficient of thermal conductivity greater than or equal to 150 W/mK (watt/meter*Kelvin temperature). In addition, the refractive index of the thermoconductive insulating layer 37 ranges between the refractive index (about 2.5) of the epitaxial layer 31 and the refractive index (about 1) of the air.

The reflective layer 38 can be an optical reflective device, a metal reflective layer, a metal dielectric reflective layer composed of dielectric films with different refractive indexes or an optical reflective device composed of micro/nano balls. In other words, the reflective layer 38 can be formed by combining or stacking a plurality of materials. The material of the reflective layer 38 can be platinum, gold, silver, palladium, nickel, chromium, titanium or combinations thereof.

As shown in FIG. 6C, the reflective layer 38 is combined with the transparent conductive layer 322 of the current spreading layer 32 in the step S24. Furthermore, as shown in FIG. 6D, the LED apparatus formed in the step S24 is turned over and the epitaxial substrate 311 is removed in the step S25.

As shown in FIG. 6E, in the step S26, a portion of the first semiconductor layer 312, a portion of the active layer 313 and a portion of the second semiconductor layer 314 are removed to expose a portion of the micro/nano roughing structure layer 321. In this embodiment, the portion of the first semiconductor layer 312, the portion of the active layer 313 and the portion of the second semiconductor layer 314 are removed by, for example but not limited to, dry etching.

Next, in the step S27, a first electrode 33 electrically connected to the micro/nano roughing structure layer 321 and a second electrode 34 electrically connected to the second semiconductor layer 314 are respectively formed to constitute another front-side LED apparatus 30 having the micro/nano structure. In this embodiment, the order of the steps is not limited thereto and can be adjusted according to the actual requirement.

### Third Embodiment

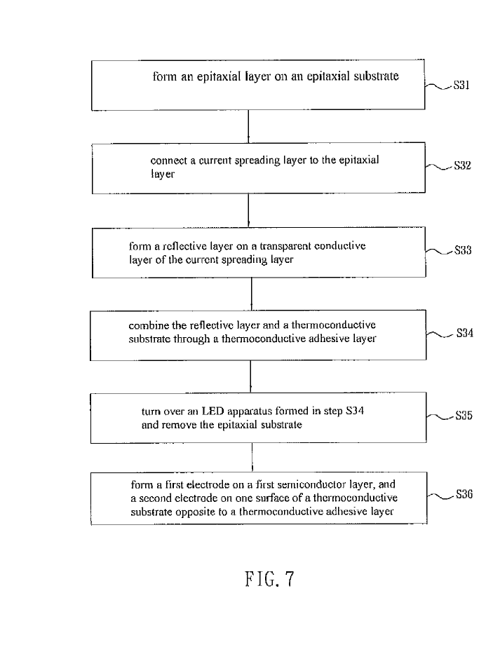

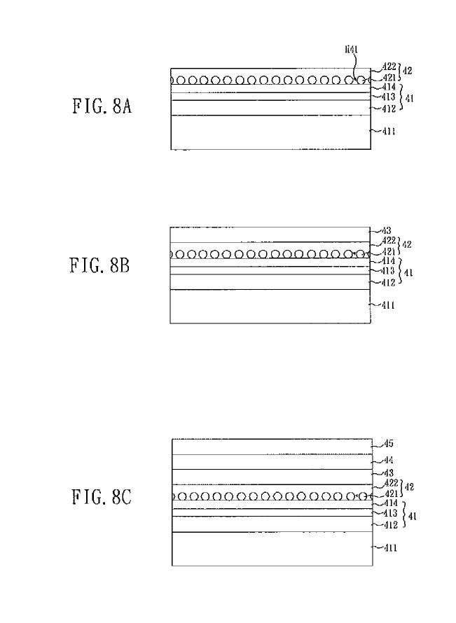

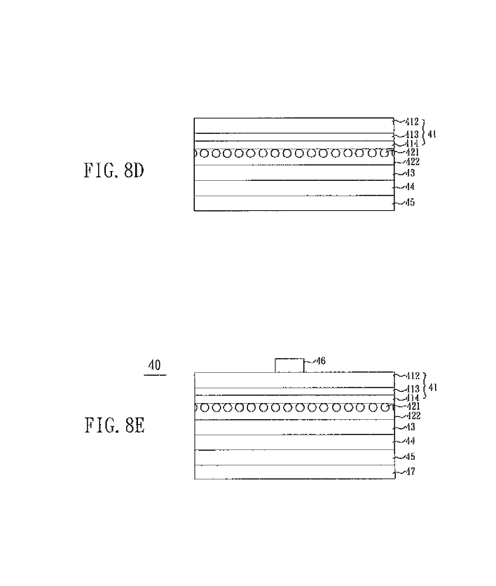

Referring to FIG. 7, a manufacturing method of a light-emitting diode (LED) apparatus according to the third embodiment of the invention includes steps S31 to S36. Illustrations will be made with reference to FIGS. 8A to 8E.

As shown in FIG. 8A, an epitaxial layer 41 is formed on an epitaxial substrate 411 in the step S31 the same as the step S11 of the first embodiment. The epitaxial layer 41 includes a first semiconductor layer 412, an active layer 413 and a second semiconductor layer 414. The first semiconductor layer 412 is formed on the epitaxial substrate 411. Next, the active layer 413 is formed on the first semiconductor layer 412 and then the second semiconductor layer 414 is formed on the active layer 413.

In the step S32, a current spreading layer 42 is connected to the epitaxial layer 41. In this embodiment, the current spreading layer 42 is formed with a micro/nano roughing structure layer 421 on the second semiconductor layer 414 by, for example but not limited to, stacking, sintering, anode aluminum oxidizing (AAO), nano-imprinting, hot pressing, etching or electron beam exposing with an E-beam writer; and the micro/nano roughing structure layer 421 has a plurality of hollow parts H41. A transparent conductive layer 422 is formed on the micro/nano roughing structure layer 421 and within the hollow parts H41.

As shown in FIG. 8B, a reflective layer 43 is formed on the transparent conductive layer 422 of the current spreading layer 42 in the step S33. As shown in FIG. 8C, a thermoconductive adhesive layer 44 combines the reflective layer 43 with a thermoconductive substrate 45 in the step S34.

As shown in FIG. 8D, a LED apparatus 40 formed in the step S34 is turned over and the epitaxial substrate 411 is removed in the step S35. As shown in FIG. 8E, a first electrode 46 is formed on the first semiconductor layer 412, and a second electrode 47 is formed on one surface of the thermoconductive substrate 45 opposite to the thermoconductive adhesive layer 44 to constitute the vertical type LED apparatus 40 having the micro/nano structure in the step S35.

In this embodiment, the materials of the layers are the same as those of the above-mentioned embodiments, so detailed descriptions thereof will be omitted. In addition, the order of the steps of this embodiment is not limited thereto and can be adjusted according to the actual requirement.

### Fourth Embodiment

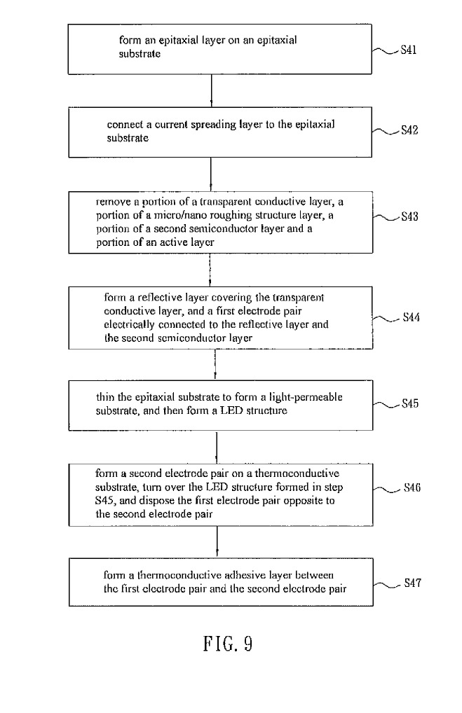

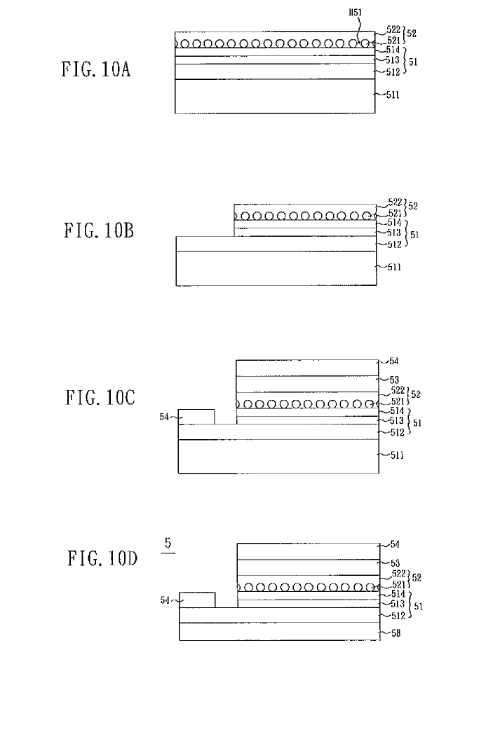

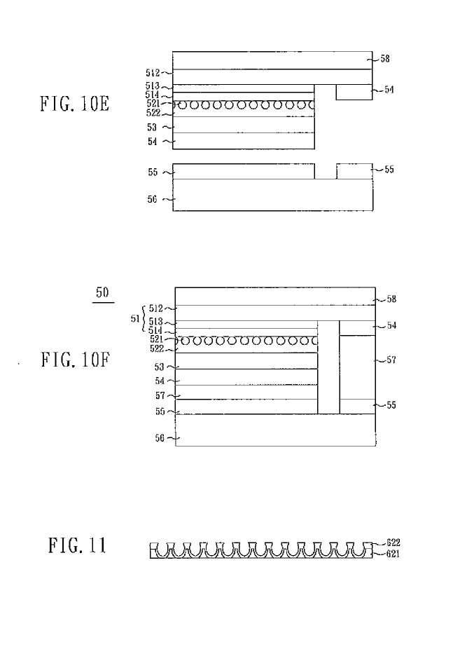

Referring to FIG. 9, a manufacturing method of a light-emitting diode (LED) apparatus 50 according to the fourth embodiment of the invention includes steps S41 to S47. Illustrations will be made with reference to FIGS. 10A to 10F.

As shown in FIG. 10A, an epitaxial layer 51 is formed on an epitaxial substrate S11 in the step S41 the same as the step S11 of the first embodiment. The epitaxial layer 51 includes a first semiconductor layer 512, an active layer 513 and a second semiconductor layer 514. The first semiconductor layer 512 is formed on the epitaxial substrate S11. Next, the active layer 513 is formed on the first semiconductor layer 512, and then the second semiconductor layer 514 is formed on the active layer 513.

In the step S42, a current spreading layer 52 is formed with a micro/nano roughing structure layer 521 on the second semiconductor layer 514 of the epitaxial layer 51 by, for example but not limited to, stacking, sintering, anode aluminum oxidizing (AAO), nano-imprinting, hot pressing, etching or electron beam exposing with an E-beam writer, and the micro/nano roughing structure layer 521 has a plurality of hollow parts H51. A transparent conductive layer 522 is formed on the micro/nano roughing structure layer 521 and within the hollow parts H51.

As shown in FIG. 10B, a portion of the transparent conductive layer 522, a portion of the micro/nano roughing structure layer 521, a portion of the second semiconductor layer 514 and a portion of the active layer 513 are removed to expose a portion of the first semiconductor layer 512 in the step S43.

As shown in FIG. 10C, a reflective layer 53 covering the transparent conductive layer 522, and a first electrode pair 54 electrically connected to the reflective layer 53 and the second semiconductor layer 514 are in sequence formed in the step S44.

As shown in FIG. 10D, the epitaxial substrate 511 is thinned to form a light-permeable substrate 58 and then to form a LED structure 5 in the step S45.

As shown in FIG. 10E, a second electrode pair 55 is formed on a thermoconductive substrate 56, the LED structure 5 formed in the step S45 is turned over, and the first electrode pair 54 is disposed opposite to the second electrode pair 55 in the step S46.

As shown in FIG. 10F, a thermoconductive adhesive layer 57 is formed between the first electrode pair 54 and the second electrode pair 55 to constitute the flip-chip type LED apparatus 50 having the micro/nano structure in the step S47.

In this embodiment, the materials of the layers are the same as those of the above-mentioned embodiments, so detailed descriptions thereof will be omitted. In addition, the order of the steps of this embodiment is not limited thereto and can be adjusted according to the actual requirement.

In addition, the current spreading layer of the above-mentioned embodiment can also have a micro/nano concave-convex structure, which is also constituted by the micro/nano roughing structure layer 521 and the transparent conductive layer 522, as shown in FIG. 11.

In summary, the current spreading layer with the micro/nano structure, the LED apparatus and its manufacturing method have the following features. First, the current spreading layer with the micro/nano structure is used in conjunction with a reflective layer, a thermoconductive insulating layer or a thermoconductive adhesive layer so that the current spreading layer with good Ohmic junction is formed in the flip-chip type, vertical type or front-side LED apparatus and the light can be well scattered by the micro/nano roughing structure. Thus, the currents can be uniformly spread, the total reflection can be decreased, and the light extracting efficiency can be enhanced.

Although the invention has been described with reference to specific embodiments, this description is not meant to be construed in a limiting sense. Various modifications of the disclosed embodiments, as well as alternative embodiments, will be apparent to persons skilled in the art. It is, therefore, contemplated that the appended claims will cover all modifications that fall within the true scope of the invention.

What is claimed is:

1. A light-emitting diode (LED) apparatus comprising:
an epitaxial layer; and
a current spreading layer connected to the epitaxial layer and having a micro/nano roughing structure layer and a transparent conductive layer, wherein the micro/nano roughing structure layer has a plurality of hollow parts, and the transparent conductive layer covers one surface of the micro/nano roughing structure layer and is filled within the hollow parts.

2. The LED apparatus according to claim 1, wherein a refractive index of the micro/nano roughing structure layer is greater than a refractive index of ail; and the micro/nano roughing structure layer comprises a nano-ball, a nano-column, a nano-hole, a nano-point, a nano-line or a nano-concave-convex structure.

3. The LED apparatus according to claim 1, wherein a material of the micro/nano roughing structure layer comprises Al₂O₃, Si₃N₄, SnO₂, SiO₂, resin, polycarbonate or combinations thereof and the micro/nano roughing structure layer is formed by stacking, sintering, anodic aluminum oxidizing (AAO), nano-imprinting, hot pressing, etching or electron beam writer (E-beam writer) processing.

4. The LED apparatus according to claim 1, wherein the epitaxial layer comprises a first semiconductor layer, an active layer and a second semiconductor layer.

5. The LED apparatus according to claim 4, wherein one of the first and second semiconductor layers is a P-type epitaxial layer and the other is an N-type epitaxial layer.

6. The LED apparatus according to claim 5, further comprising:
a reflective layer connected to one surface of the current spreading layer opposite to the second semiconductor layer; and
a first electrode pair disposed on the reflective layer and the first semiconductor layer, respectively.

7. The LED apparatus according to claim 6, wherein a material of the reflective layer comprises platinum (Pt), gold (Au), silver (Ag), palladium (Pd), nickel (Ni), chromium (Cr), titanium (Ti) or combinations thereof, and the reflective layer is an optical reflective device composed of dielectric films with different refractive indexes, a metal reflective layer; a metal dielectric reflective layer or an optical reflective device composed of micro/nano balls.

8. The LED apparatus according to claim 6, further comprising:
a thermoconductive substrate;
a second electrode pair disposed on the thermoconductive substrate and disposed opposite to the first electrode pair; and
a thermoconductive adhesive layer disposed between the first electrode pair and the second electrode pair.

9. The LED apparatus according to claim 8, wherein a material of the thermoconductive substrate comprises silicon, gallium arsenide, gallium phosphide, silicon carbide, boron nitride, aluminum, aluminum nitride, copper or combinations thereof, and a material of the thermoconductive adhesive layer comprises gold, a solder paste, a solder-silver paste, a silver paste or combinations thereof.

10. The LED apparatus according to claim 8, further comprising a light-permeable substrate disposed on one surface of the first semiconductor layer opposite to the active layer for supporting the epitaxial layer.

11. The LED apparatus according to claim 5, further comprising:
a thermoconductive substrate;
a thermoconductive adhesive layer disposed on the thermoconductive substrate;
a thermoconductive insulating layer disposed on the thermoconductive adhesive layer; and
a reflective layer disposed on the thermoconductive insulating layer and connected to one surface of the current spreading layer opposite to the second semiconductor layer.

12. The LED apparatus according to claim 11, wherein a material of the thermoconductive substrate comprises silicon, gallium arsenide, gallium phosphide, silicon carbide, boron nitride, aluminum, aluminum nitride, copper or combinations thereof, and a material of the thermoconductive adhesive layer comprises gold, a solder paste, a solder-silver paste, a silver paste or combinations thereof.

13. The LED apparatus according to claim 11, wherein a material of the reflective layer comprises platinum (Pt), gold (Au), silver (Ag), palladium (Pd), nickel (Ni), chromium (Cr), titanium (Ti) or combinations thereof, and the reflective layer is an optical reflective device composed of dielectric films with different refractive indexes, a metal reflective layer; a metal dielectric reflective layer or an optical reflective device composed of micro/nano balls.

14. The LED apparatus according to claim 11, wherein a material of the thermoconductive insulating layer is an insulating material having a coefficient of thermal conductivity greater than or equal to 150 W/mK, and a material of the thermoconductive insulating layer is aluminum nitride or silicon carbide.

15. The LED apparatus according to claim 11, wherein a refractive index of the thermoconductive insulating layer is greater than that of air, and smaller than that of the epitaxial layer.

16. The LED apparatus according to claim 11, further comprising a first electrode disposed on the first semiconductor layer and a second electrode disposed on the current spreading layer, and a portion of the current spreading layer is exposed.

17. The LED apparatus according to claim 5, further comprising an epitaxial substrate, a first electrode and a second electrode, wherein the first semiconductor layer, the active layer and the second semiconductor layer of the epitaxial layer are formed on the epitaxial substrate, and the first and second electrodes are electrically connected to a portion of the first semiconductor layer and a portion of the transparent conductive layer, respectively.

18. The LED apparatus according to claim 17, further comprising a thermoconductive insulating layer formed on a portion of the current spreading layer.

19. The LED apparatus according to claim 5, further comprising:
a thermoconductive substrate;
a thermoconductive adhesive layer disposed on the thermoconductive substrate;
a reflective layer disposed on the thermoconductive adhesive layer and connected to one surface of the current spreading layer opposite to the first semiconductor layer;
a first electrode disposed on the first semiconductor layer; and
a second electrode disposed on a surface of the thermoconductive substrate opposite to the thermoconductive adhesive layer.

20. The LED apparatus according to claim 19, wherein a material of the thermoconductive substrate comprises silicon, gallium arsenide, gallium phosphide, silicon carbide, boron nitride, aluminum, aluminum nitride, copper or combinations thereof and a material of the thermoconductive adhesive layer comprises gold, a solder paste, a solder-silver paste, a silver paste or combinations thereof.

21. The LED apparatus according to claim 19, wherein a material of the reflective layer comprises platinum (Pt), gold (Au), silver (Ag), palladium (Pd), nickel (Ni), chromium (Cr), titanium (Ti) or combinations thereof, and the reflective layer is an optical reflective device composed of dielectric films with different refractive indexes, a metal reflective layer, a metal dielectric reflective layer or an optical reflective device composed of micro/nano balls.

22. The LED apparatus according to claim 5, wherein a material of the transparent conductive layer comprises indium tin oxide (ITO), aluminum-doped zinc oxide (AZO) or indium zinc oxide (IZO).

23. A manufacturing method of a light-emitting diode (LED) apparatus, comprising steps of:
forming a first semiconductor layer, and an active layer and a second semiconductor layer on an epitaxial substrate;
forming a micro/nano roughing structure layer with a plurality of hollow pales on the second semiconductor layer; and
forming a transparent conductive layer on the micro/nano roughing structure layer and within the hollow parts.

24. The method according to claim 23, further comprising steps of:
removing a portion of the active layer and a portion of the second semiconductor layer to expose a portion of the first semiconductor layer;
forming a first electrode electrically connected to the first semiconductor layer; and
forming a second electrode electrically connected to the second semiconductor layer.

25. The method according to claim 24, further comprising forming a thermoconductive insulating layer on a portion of the current spreading layer.

26. The method according to claim 23, further comprising steps of:
forming a thermoconductive adhesive layer on a thermoconductive substrate;
forming a thermoconductive insulating layer on the thermoconductive adhesive layer;
forming a reflective layer on the thermoconductive insulating layer;
combining the transparent conductive layer with the reflective layer;
removing the epitaxial substrate;
removing a portion of the first semiconductor layer, a portion of the active layer and a portion of the second semiconductor layer to expose a portion of the micro/nano roughing structure layer;
forming a first electrode electrically connected to the micro/nano roughing structure layer; and
forming a second electrode electrically connected to the second semiconductor layer.

27. The method according to claim 23, further comprising steps of:
forming a reflective layer on the transparent conductive layer;
combining the reflective layer with a thermoconductive substrate through a thermoconductive adhesive layer;
turning over the LED apparatus;
forming a first electrode on the first semiconductor layer after removing the epitaxial substrate; and
forming a second electrode on one surface of the thermoconductive substrate opposite to the thermoconductive adhesive layer.

28. The method according to claim 23, further comprising steps of:
removing a portion of the transparent conductive layer, a portion of the micro/nano roughing structure layer, a portion of the second semiconductor layer and a portion of the active layer to expose a portion of the first semiconductor layer;
forming a reflective layer on the transparent conductive layer; and
thinning the epitaxial substrate to form a light-permeable substrate;
turning over the LED apparatus;
forming a first electrode pair electrically connected to the reflective layer and the second semiconductor layer;
forming a second electrode pair on a thermoconductive substrate; and
forming a thermoconductive adhesive layer between the first electrode pair and the second electrode pair.

29. The method according to claim 23, wherein the micro/nano roughing structure layer is formed by stacking, sintering, anodic aluminum oxidizing (AAO), nano-imprinting, hot pressing, etching or electron beam writer (E-beam writer) processing.
